(19) United States
(12) Patent Application Publication
(10) Pub. No.: US 2022/0172777 A1
(43) Pub. Date: Jun. 2, 2022

(54) MEMORY CONTROL CIRCUIT

(71) Applicant: SONY SEMICONDUCTOR SOLUTIONS CORPORATION, KANAGAWA (JP)

(72) Inventors: HARUHIKO TERADA, KANAGAWA (JP); YOSHIYUKI SHIBAHARA, KANAGAWA (JP); YOTARO MORI, KANAGAWA (JP)

(21) Appl. No.: 17/436,453

(22) PCT Filed: Jan. 30, 2020
(86) PCT No.: PCT/JP2020/003476

§ 371 Date: Sep. 3, 2021

(30) Foreign Application Priority Data
Mar. 19, 2019 (JP) 2019-050584

(51) Int. Cl. G11C 13/00

(52) U.S. Cl. CPC G11C 13/004; G11C 13/0069; G11C 13/0028; G11C 13/0026; G11C 13/0038

(57) ABSTRACT

In a circuit that selects a memory cell and applies a predetermined voltage to two ends of the memory cell, a withstand voltage and a maximum amplitude of a gate voltage are reduced. A memory control circuit includes a plurality of stages of memory decoders configured to select a specific cell of a memory according to a specified address and apply a predetermined voltage to two ends of the specific cell. At least one of the plurality of stages of the memory decoders includes the following four transistors. A first transistor and a second transistor are each provided according to a value to be written to the specific cell. A third transistor and a fourth transistor are provided to bring the specific cell into a non-selected state.

### TECHNICAL FIELD

The present technology relates to a memory control circuit. More specifically, the present technology relates to a memory control circuit that selects a specific cell of a memory according to a specified address and applies a predetermined voltage to two ends of the specific cell.

### BACKGROUND ART

In recent years, as a next-generation non-volatile memory, a resistance change type memory that uses variable resistance elements or phase change elements as memory cells has been developed. As this resistance change type memory, a cross-point memory having a structure in which memory cells are formed at intersections of a plurality of wirings arranged vertically and horizontally is known. For example, a semiconductor storage device that compensates for a voltage drop of a selected word line by using coupling between word lines has been proposed (see, for example, Patent Document 1).

### CITATION LIST

### Patent Document

Patent Document 1: Japanese Patent Application Laid-Open No. 2013-200937

### SUMMARY OF THE INVENTION

### Problems to be Solved by the Invention

In the above-described conventional technique, the voltage is controlled in the cross-point memory. However, in such a memory, the voltage to be applied is high, and as transistors used in a memory drive circuit such as a decoder, transistors having a high gate-to-diffusion region voltage and a high maximum amplitude of gate voltage are required. Then, this causes a problem that the area required for the transistors becomes large and the power consumption becomes high. In the cross-point memory, since a large portion of the memory drive circuit including the decoder is mounted under a memory cell array, it is necessary to miniaturize the memory drive circuit in parallel with miniaturization of the memory cell array, in order to miniaturize the entire memory.

The present technology has been created in view of such a situation, and has an object to reduce withstand voltage and maximum amplitude of a gate voltage in a circuit that selects a cell of the memory and applies a predetermined voltage to two ends of the cell.

### Solutions to Problems

The present technology has been made to solve the above-mentioned problems, and a first aspect thereof is a memory control circuit including a plurality of stages of memory decoders configured to select a specific cell of a memory according to a specified address and apply a predetermined voltage to two ends of the specific cell, in which a first specific stage that is at least one of the plurality of stages includes a first transistor and a second transistor each provided according to a value to be written to the specific cell, and a third transistor and a fourth transistor that bring the specific cell into a non-selected state. This arrangement provides an operation of reducing a withstand voltage and a maximum amplitude of a gate voltage of the transistors used in the memory decoders.

Furthermore, in the first aspect, the first and second transistors may have outputs connected to each other and become exclusively conductive. This arrangement provides an operation of applying a necessary voltage from either of the transistors.

Furthermore, in the first aspect, the first transistor may become conductive either when writing a first value to the specific cell or when reading a value from the specific cell, and the second transistor may become conductive when writing a second value to the specific cell. This arrangement provides an operation of applying a necessary voltage from the first transistor when writing and reading the first value, and applying a necessary voltage from the second transistor when writing the second value.

Furthermore, in the first aspect, the third and fourth transistors may be connected in series, and when bringing the specific cell into the non-selected state, the third and fourth transistors may become conductive and apply a voltage to a non-selection line. This arrangement provides an operation of applying a necessary voltage from the third and fourth transistors when bringing the cell into the non-selected state.

Furthermore, in the first aspect, a maximum value of a gate-to-diffusion region voltage of the first to fourth transistors may be smaller than the voltage applied to the two ends of the specific cell. This arrangement provides an operation of making it possible to use ones having a small maximum value of the gate-to-diffusion region voltage as the first to fourth transistors.

Furthermore, in the first aspect, a maximum amplitude of a gate voltage of the first to fourth transistors may be smaller than the voltage applied to the two ends of the specific cell. This arrangement provides an operation of making it possible to use ones having a small maximum amplitude of the gate voltage as the first to fourth transistors.

Furthermore, in this first aspect, a second specific stage that is at least one stage of the memory decoders other than the first specific stage may include a driver that generates voltages with three values, and a fifth transistor and a sixth transistor that become exclusively conductive according to an output of the driver. This arrangement provides an operation of reducing the withstand voltage and the maximum amplitude of the gate voltage of the transistors used in the memory decoders.

Furthermore, in the first aspect, the fifth transistor may become conductive by a highest voltage among the three values either when writing the first value to the specific cell or when reading a value from the specific cell, and become conductive by an intermediate voltage of the three values when writing the second value to the specific cell. This arrangement provides an operation of applying a necessary voltage from the fifth transistor when writing and reading.

Furthermore, in the first aspect, when bringing the specific cell into the non-selected state, the sixth transistor may become conductive and apply a voltage to a non-selection line. This arrangement provides an operation of applying the necessary voltage from the sixth transistor when bringing the cell into the non-selected state.

Furthermore, in the first aspect, in a case where the memory decoder above the second specific stage is in a non-selected state, the fifth transistor may become conductive and apply a voltage to a non-selection line. This arrangement provides an operation of applying the necessary voltage from the fifth transistor when bringing the cell into the non-selected state.

Furthermore, in the first aspect, the second specific stage may be arranged on a side of the memory with respect to the first specific stage. This arrangement provides an operation, in the second specific stage having a large number of decoders, of lowering the withstand voltage and the maximum amplitude of the gate voltage while suppressing the number of transistors.

Furthermore, in the first aspect, the memory may be a cross-point memory, the specific cell may be arranged at an intersection of a bit line and a word line, and the plurality of stages of the memory decoders may be provided for each of the bit line and the word line. This arrangement provides an operation of reducing the withstand voltage and the maximum amplitude of the gate voltage of the transistors used in the memory control circuit mounted under a memory cell array of the cross-point memory.

Furthermore, a second aspect of the present technology is a memory control circuit including a plurality of stages of memory decoders configured to select a specific cell of a memory according to a specified address and apply a predetermined voltage to two ends of the specific cell, in which a specific stage that is at least one of the plurality of stages includes a driver that generates voltages with three values, and a first transistor and a second transistor that become exclusively conductive according to an output of the driver. This arrangement provides an operation of reducing the withstand voltage and the maximum amplitude of the gate voltage of the transistors used in the memory decoders.

Furthermore, in the second aspect, the first transistor may become conductive by a highest voltage among the three values either when writing a first value to the specific cell or when reading a value from the specific cell, and become conductive by an intermediate voltage of the three values when writing a second value to the specific cell. This arrangement provides an operation of applying the necessary voltage from the first transistor when writing and reading.

Furthermore, in the second aspect, when bringing the specific cell into a non-selected state, the second transistor may become conductive and apply a voltage to a non-selection line. This arrangement provides an operation of applying the necessary voltage from the second transistor when bringing the cell into the non-selected state.

Furthermore, in the second aspect, in a case where the memory decoder above the specific stage is in a non-selected state, the first transistor may become conductive and apply a voltage to a non-selection line. This arrangement provides an operation of applying the necessary voltage from the first transistor when bringing the cell into the non-selected state.

Furthermore, in this second aspect, a maximum value of a gate-to-diffusion region voltage of the first and second transistors may be smaller than the voltage applied to the two ends of the specific cell. This arrangement provides an operation of making it possible to use ones having a small maximum value of the gate-to-diffusion region voltage as the first and second transistors.

Furthermore, in this second aspect, a maximum amplitude of a gate voltage of the first and second transistors may be smaller than the voltage applied to the two ends of the specific cell. This arrangement provides an operation of making it possible to use ones having a small maximum amplitude of the gate voltage as the first and second transistors.

### BRIEF DESCRIPTION OF DRAWINGS

FIG. 1 is a diagram illustrating an example of an overall configuration of a memory system in an embodiment of the present technology.

FIG. 2 is a diagram illustrating a configuration example of a bit line decoder 200 in a first embodiment of the present technology.

FIG. 3 is a diagram illustrating a configuration example of a bit line bias control circuit 400 in the first embodiment of the present technology.

FIG. 4 is a diagram illustrating a configuration example of a ternary gate driver 220 in the embodiment of the present technology.

FIG. 5 is a diagram illustrating an example of a truth table of the ternary gate driver 220 in the embodiment of the present technology.

FIG. 6 is a diagram illustrating an example of a truth table of a global bit line decoder 230 in the embodiment of the present technology.

FIG. 7 is a diagram illustrating an example of a voltage state of set operation or sense operation of the bit line decoder 200 in the first embodiment of the present technology.

FIG. 8 is a diagram illustrating a first example of a voltage state of non-selective operation of the bit line decoder 200 in the first embodiment of the present technology.

FIG. 9 is a diagram illustrating a second example of a voltage state of non-selective operation of the bit line decoder 200 in the first embodiment of the present technology.

FIG. 10 is a diagram illustrating an example of a voltage state of reset operation of the bit line decoder 200 in the first embodiment of the present technology.

FIG. 11 is a diagram illustrating a configuration example of a word line decoder 300 in the first embodiment of the present technology.

FIG. 12 is a diagram illustrating a configuration example of a word line bias control circuit 500 in the first embodiment of the present technology.

FIG. 13 is a diagram illustrating a configuration example of a ternary gate driver 320 in the embodiment of the present technology.

FIG. 14 is a diagram illustrating an example of a truth table of the ternary gate driver 320 in the embodiment of the present technology.

FIG. 15 is a diagram illustrating an example of a truth table of a global word line decoder 330 in the first embodiment of the present technology.

FIG. 16 is a diagram illustrating an example of a voltage state of set operation or sense operation of the word line decoder 300 in the first embodiment of the present technology.

FIG. 17 is a diagram illustrating a first example of a voltage state of non-selective operation of the word line decoder 300 in the first embodiment of the present technology.

FIG. 18 is a diagram illustrating a second example of a voltage state of non-selective operation of the word line decoder 300 in the first embodiment of the present technology.

FIG. 19 is a diagram illustrating an example of a voltage state of reset operation of the word line decoder 300 in the first embodiment of the present technology.

FIG. 20 is a diagram illustrating an example of a voltage state of floating operation of the word line decoder 300 in the first embodiment of the present technology.

FIG. 21 is a diagram illustrating a modification example of the global bit line decoder 230 in the first embodiment of the present technology.

FIG. 22 is a diagram illustrating a structural example of a cross-point memory array 100 in a second embodiment of the present technology.

FIG. 23 is a diagram illustrating a configuration example of a bit line decoder 200 in the second embodiment of the present technology.

FIG. 24 is a diagram illustrating a configuration example of a bit line bias control circuit 400 in the second embodiment of the present technology.

FIG. 25 is a diagram illustrating a configuration example of a word line decoder 300 in the second embodiment of the present technology.

FIG. 26 is a diagram illustrating a configuration example of a word line bias control circuit 500 in the second embodiment of the present technology.

### MODE FOR CARRYING OUT THE INVENTION

Hereinafter, modes for carrying out the present technology (hereinafter referred to as embodiments) will be described. The description will be given in the following order.

1. First embodiment (example of application to cross-point memory)

2. Second embodiment (example of application to two-layer cross-point memory)

### 1. First Embodiment

[Memory System]

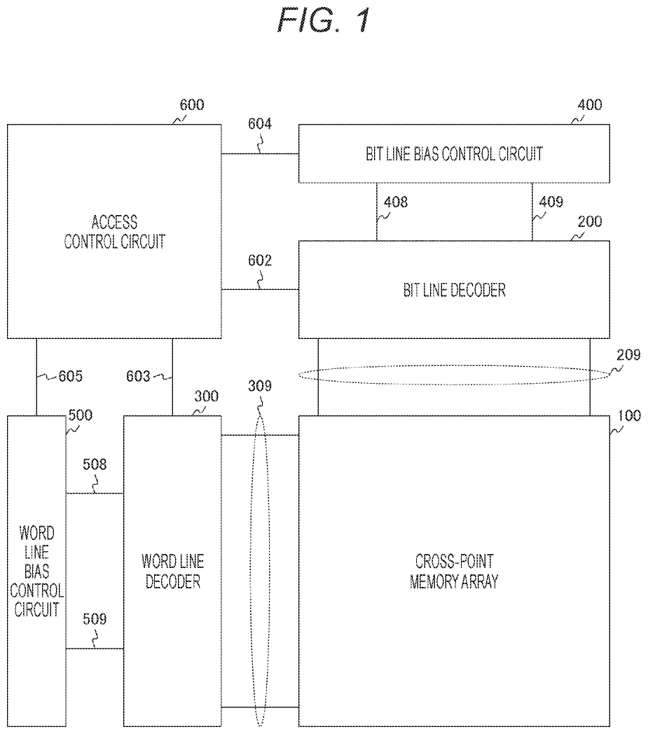

FIG. 1 is a diagram illustrating an example of an overall configuration of a memory system in an embodiment of the present technology.

This memory system includes a cross-point memory array 100, a bit line decoder 200, a word line decoder 300, a bit line bias control circuit 400, a word line bias control circuit 500, and an access control circuit 600.

The cross-point memory array 100 is a non-volatile memory in which memory cells are arranged respectively at intersections of a plurality of vertically extending bit lines and a plurality of horizontally extending word lines. In this embodiment, as an example, memory cells of a total of 1 M (1024×1024) bits are arranged respectively at intersections of 1024 bit lines and 1024 word lines. Here, a resistance change type storage element is assumed as the memory cells.

The bit line decoder 200 is an address decoder that decodes a bit line among specified addresses. In this example, as will be described later, a two-stage decoder is provided, and multi-stage decoding is performed so as to select 32 lines from 1024 lines and select one line from 32 lines. Thus, one bit line is selected from the 1024 signal lines 209, and a predetermined voltage is applied thereto. Furthermore, for other bit lines, for example, 0 V is applied as a non-selection line.

The word line decoder 300 is an address decoder that decodes a word line among specified addresses. In this example, as will be described later, a two-stage decoder is provided, and multi-stage decoding is performed so as to select 32 lines from 1024 lines and select one line from 32 lines. Thus, one word line is selected from 1024 signal lines 309, and a predetermined voltage is applied thereto. Furthermore, for other word lines, for example, 0 V is applied as a non-selection line. Note that the word line may be temporarily set to high impedance.

The bit line bias control circuit 400 is a circuit that controls a bias voltage supplied to the bit line decoder 200. The bias voltage by the bit line bias control circuit 400 is supplied to the bit line decoder 200 via signal lines 408 and 409.

The word line bias control circuit 500 is a circuit that controls a bias voltage supplied to the word line decoder 300. The bias voltage by the word line bias control circuit 500 is supplied to the word line decoder 300 via signal lines 508 and 509.

The access control circuit 600 is a circuit that controls access to the cross-point memory array 100 according to a command and an address specified from a host computer or the like outside the memory system. The access control circuit 600 supplies an address signal corresponding to a bit line to the bit line decoder 200 via a signal line 602. Further, the access control circuit 600 supplies an address signal corresponding to a word line to the word line decoder 300 via a signal line 603. Furthermore, the access control circuit 600 supplies a command signal to the bit line bias control circuit 400 via the signal line 604. Further, the access control circuit 600 supplies a command signal to the word line bias control circuit 500 via a signal line 605.

[Bit Line Decoder]

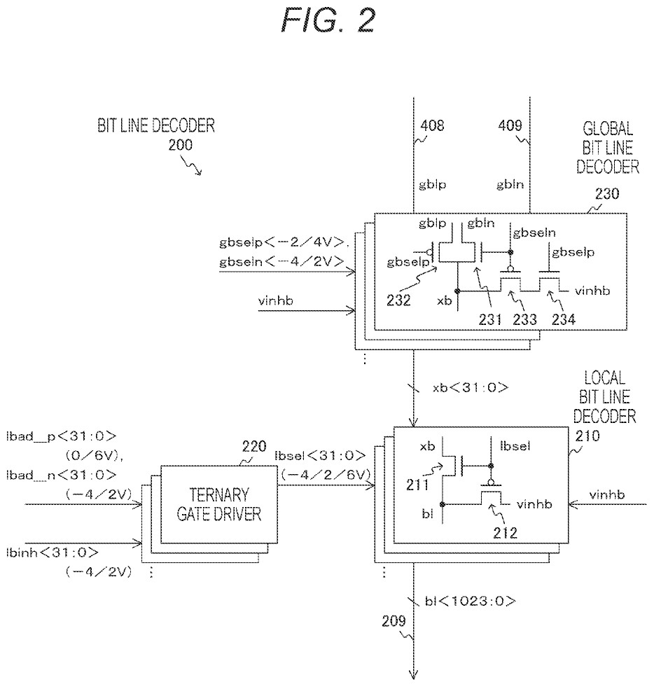

FIG. 2 is a diagram illustrating a configuration example of the bit line decoder 200 in the first embodiment of the present technology.

The bit line decoder 200 includes local bit line decoders 210, ternary gate drivers 220, and global bit line decoders 230. Note that the local bit line decoders 210 are an example of a specific stage and a second specific stage described in the claims. Further, the ternary gate drivers 220 are an example of a driver described in the claims. Furthermore, the global bit line decoders 230 are an example of a first specific stage described in the claims.

The local bit line decoders 210 and the global bit line decoders 230 are address decoders that decode a bit line among specified addresses. In this example, the local bit line decoders 210 select 32 lines from 1024 lines, and the global bit line decoders 230 select one line from 32 lines. In this case, 1024 local bit line decoders 210 are needed and 32 global bit line decoders 230 are needed. That is, the signal lines 209 are 1024 bit line signals bl <1023:0>, and the local bit line decoders 210 cause only one line to be in a selected state and the other 1023 lines to be in a non-selected state.

Each of the global bit line decoders 230 includes four transistors 231 to 234. The transistor 231 is an nMOS transistor, and turns on (conductive) and sets the potential of output xb to gbln when a gate signal gbseln is at a high (H) level. The transistor 232 is a pMOS transistor, and turns on and sets the potential of the output xb to gblp when a gate signal gbselp is at a low (L) level. That is, the transistors 231 and 232 have outputs connected to each other and become exclusively conductive. As will be described later, the gblp is the bias voltage supplied from the bit line bias control circuit 400 via the signal line 408, and the gbln is the bias voltage supplied from the bit line bias control circuit 400 via the signal line 409.

The transistors 233 and 234 are connected in series. The transistor 233 is a pMOS transistor and turns on when the gate signal gbseln is at L level. The transistor 234 is an nMOS transistor and turns on when the gate signal gbselp is at H level. Accordingly, both the transistors 233 and 234 turn on and set the potential of the output xb to vinhb when the gbseln is at L level and the gbselp is at H level. The vinhb is a voltage indicating inhibit meaning non-selection, and is 0 V for example.

Each of the local bit line decoders 210 includes two transistors 211 and 212. The transistor 211 is an nMOS transistor, and turns on and sets the potential of output bl to the xb when a gate signal lbsel is at H level. Here, the xb is an output of the corresponding global bit line decoder 230. The transistor 212 is a pMOS transistor, and turns on and sets the potential of the output bl to the vinhb when the gate signal lbsel is at L level. Accordingly, the potential of the output bl becomes the output xb of the corresponding global bit line decoder 230 when the lbsel is at H level, and the vinhb when the lbsel is at L level.

However, the transistors 211 and 212 can be used by switching a drive voltage. The gate voltage lbsel has any of three values of high potential, medium potential, and low potential. In a case of operating by high voltage driving, the high potential is at H level and the medium potential or lower is at L level. In a case of operating by low voltage driving, the medium potential and above are H level, and the low potential is L level. These gate voltages of three values are supplied by a ternary gate driver 220.

The ternary gate driver 220 supplies the gate voltage lbsel of the transistors 211 and 212 of the local bit line decoder 210. In this example, it is assumed that the ternary gate driver 220 outputs one of three values of 6 V (high potential), 2 V (medium potential), and −4 V (low potential).

[Bit Line Bias Control Circuit]

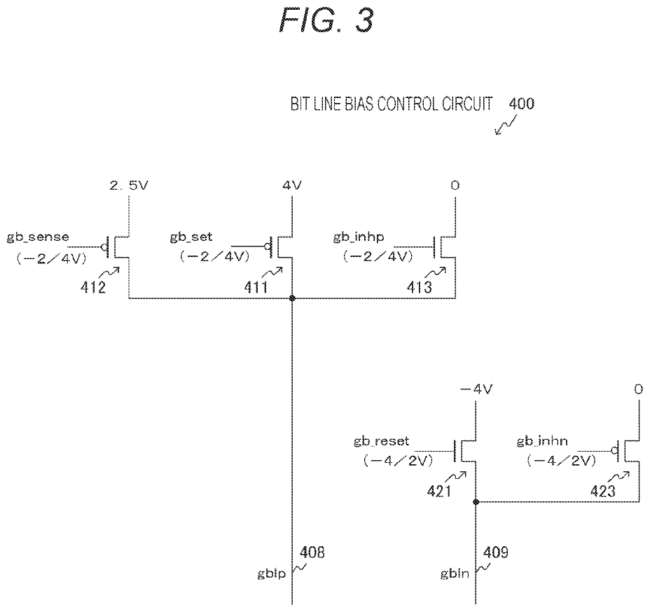

FIG. 3 is a diagram illustrating a configuration example of the bit line bias control circuit 400 in the first embodiment of the present technology.

The bit line bias control circuit 400 includes five transistors 411 to 413, 421, and 423.

The transistor 411 is a pMOS transistor and turns on when a gate signal gb_set is at L level. In this example, it turns on and sets the bias voltage gblp of the signal line 408 to 4 V when the gb_set is −2 V. That is, the bias voltage gblp of 4 V is supplied for set operation.

The transistor 412 is a pMOS transistor and turns on when a gate signal gb_sense is at L level. In this example, it turns on and sets the bias voltage gblp of the signal line 408 to 2.5 V when the gb_sense is −2 V. That is, the bias voltage gblp of 2.5 V is supplied for sense operation.

The transistor 413 is an nMOS transistor and turns on when a gate signal gb_inhp is at H level. In this example, it turns on and sets the bias voltage gblp of the signal line 408 to 0 V when the gb_inhp is 4 V. That is, the bias voltage gblp of 0 V is supplied for non-selective operation.

The transistor 421 is an nMOS transistor and turns on when a gate signal gb_reset is at H level. In this example, it turns on and sets the bias voltage gbln of the signal line 409 to −4 V when the gb_reset is 2 V. That is, the bias voltage gbln of −4 V is supplied for reset operation.

The transistor 423 is a pMOS transistor and turns on when a gate signal gb_inhn is at L level. In this example, it turns on and sets the bias voltage gbln of the signal line 409 to 0 V when the gb_inhn is −4 V. That is, the bias voltage gbln of 0 V is supplied for non-selective operation.

Thus, gate voltages of the transistors 411 to 413 are −2 V or 4 V, having an amplitude of 6 V. Furthermore, gate voltages of the transistors 421 and 423 are −4 V or 2 V, having an amplitude of 6 V.

[Ternary Gate Driver]

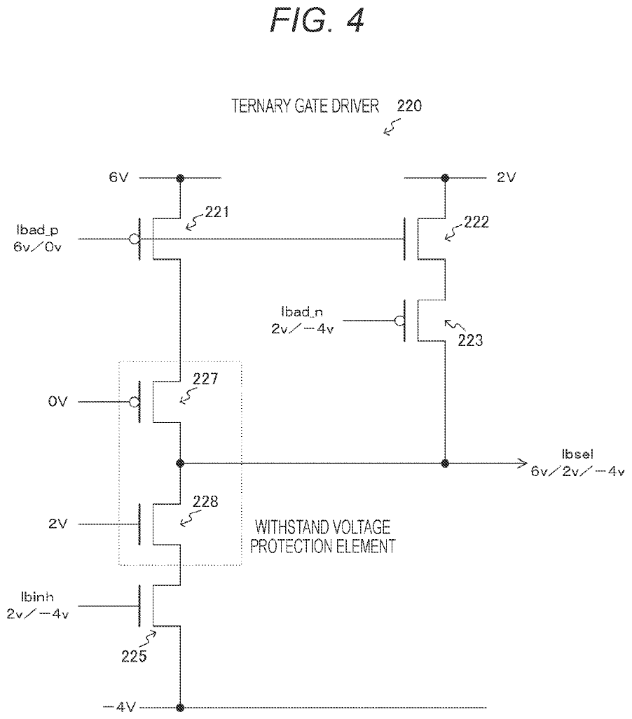

FIG. 4 is a diagram illustrating a configuration example of the ternary gate driver 220 in the embodiment of the present technology.

The ternary gate driver 220 includes six transistors 221 to 223, 225, 227, and 228.

The transistor 221 is a pMOS transistor and turns on when a gate signal lbad_p is at L level. The transistor 222 is an nMOS transistor and turns on when the gate signal lbad_p is at H level. The transistor 223 is a pMOS transistor and turns on when a gate signal lbad_n is at L level. The transistor 225 is an nMOS transistor and turns on when a gate signal lbinh is at H level.

Gate voltages of the transistors 221 and 222 are 0 V or 6 V, having an amplitude of 6 V. Furthermore, gate voltages of the transistors 223 and 225 are −4 V or 2 V, having an amplitude of 6 V.

The transistor 227 is a pMOS transistor, and 0 V is fixedly input as a gate signal. The transistor 228 is an nMOS transistor, and 2 V is fixedly input as a gate signal. These transistors 227 and 228 are withstand voltage protection elements. For example, when the gate signal lbad_p is 6 V, if the source of the withstand voltage protection element becomes a negative potential, the voltage between the gate and drain of the transistor 221 exceeds 6 V and a withstand voltage problem occurs, and thus the withstand voltage protection element functions so as to avoid becoming the negative potential.

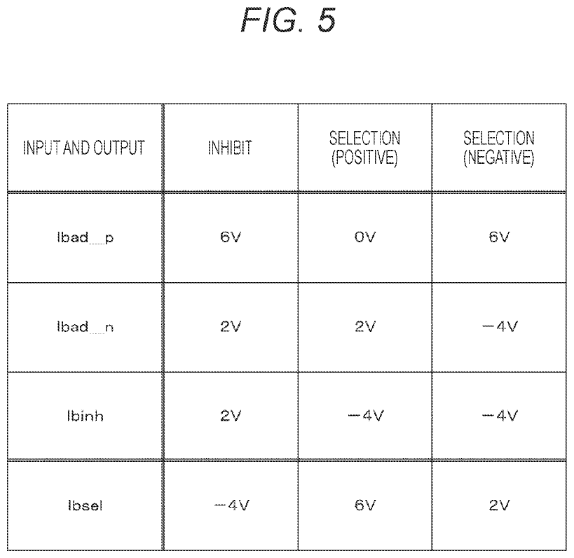

FIG. 5 is a diagram illustrating an example of a truth table of the ternary gate driver 220 in the embodiment of the present technology.

The ternary gate driver 220 supplies a potential of any of selection (positive), selection (negative), and inhibit according to the lbad_p, lbad_n, and lbinh as the gate voltage lbsel of the transistors 211 and 212 of the local bit line decoder 210. In this example, the selection (positive) is a voltage for set operation or sense operation and is 6 V (high potential). Furthermore, the selection (negative) is a voltage for reset operation and is 2 V (medium potential). The inhibit is a voltage for non-selective operation and is −4 V (low potential).

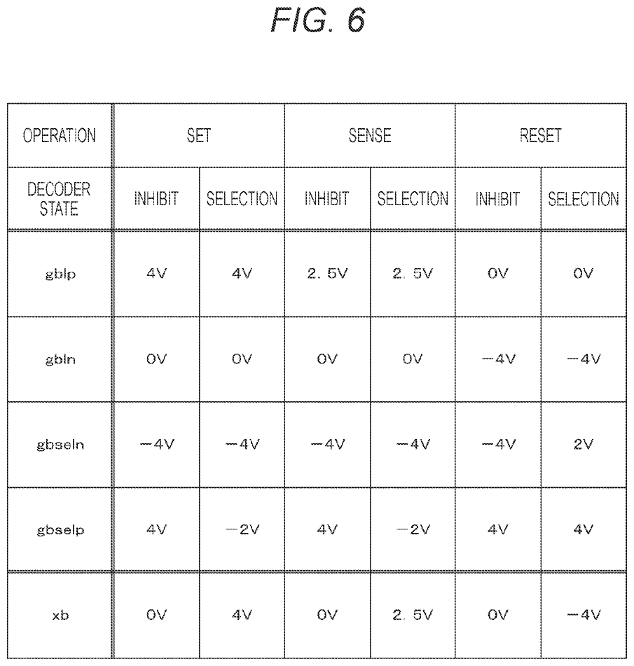

FIG. 6 is a diagram illustrating an example of a truth table of the global bit line decoder 230 in the embodiment of the present technology. Details of each operation will be described below.

[Voltage in Bit Line Decoder]

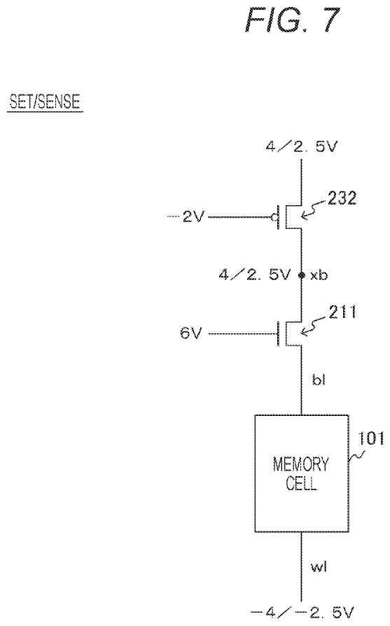

FIG. 7 is a diagram illustrating an example of a voltage state of set operation or sense operation of the bit line decoder 200 in the first embodiment of the present technology.

The set operation is operation of setting a memory cell 101 to a low resistance state (LRS) and writing a value “1”, and at this time, the bit line bl of the selected memory cell 101 is set to 4 V and the word line wl is set to −4 V.

The sense operation is an operation of reading the state of the memory cell 101, and at this time, the bit line bl of the selected memory cell 101 is set to 2.5 V, and the word line wl is set to −2.5 V.

The gbselp of the selected global bit line decoder 230 becomes −2 V, and thus the transistor 232 turns on. Accordingly, the output xb becomes the same value as the gblp. During the set operation, the gblp is 4 V, and during the sense operation, the gblp is 2.5 V.

The lbsel of the local bit line decoder 210 selected during the set operation or the sense operation becomes 6 V, and thus the transistor 211 turns on. Accordingly, the output bl becomes the same value as the gblp. Therefore, to the bit line bl of the memory cell 101, 4 V is applied during the set operation, and 2.5 V is applied during the sense operation.

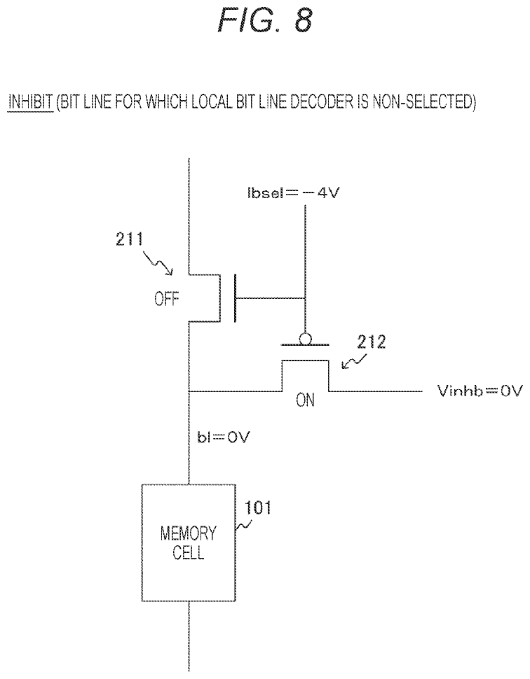

FIG. 8 is a diagram illustrating a first example of a voltage state of the non-selective operation of the bit line decoder 200 in the first embodiment of the present technology.

Here, a bit line for which the local bit line decoder 210 is non-selected is assumed. In this case, the lbsel is −4 V (low potential). Thus, the transistor 211 turns off and the transistor 212 turns on. Accordingly, the output bl becomes 0 V, which is the same as the vinhb. That is, the memory cell 101 becomes a non-selected state.

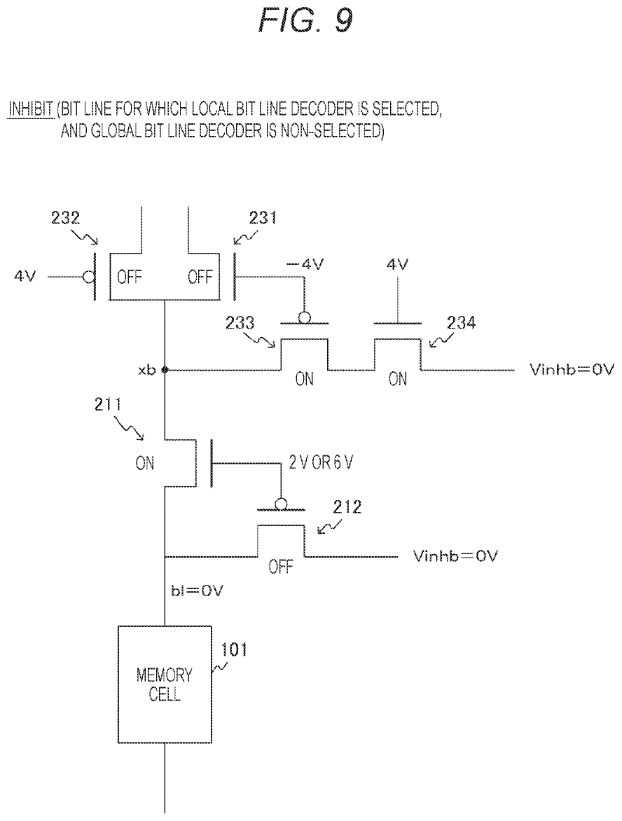

FIG. 9 is a diagram illustrating a second example of a voltage state of the non-selective operation of the bit line decoder 200 in the first embodiment of the present technology.

Here, a bit line for which the local bit line decoder 210 is selected and the global bit line decoder 230 is non-selected is assumed. In this case, the gbselp is 4 V and the gbseln is −4 V. Thus, the transistors 231 and 232 turn off, and the transistors 233 and 234 turn on. Accordingly, the output xb becomes 0 V, which is the same as the vinhb.

Furthermore, in this case, the lbsel becomes 6 V (high potential) or 2 V (medium potential). Thus, the transistor 211 turns on and the transistor 212 turns off. Accordingly, the output bl becomes 0 V, which is the same as the xb. That is, the memory cell 101 becomes a non-selected state.

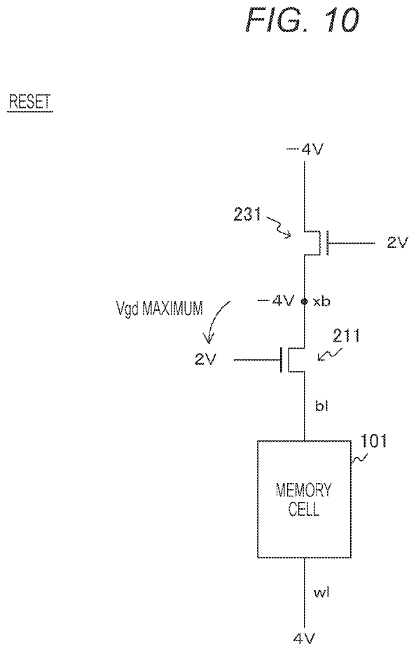

FIG. 10 is a diagram illustrating an example of a voltage state of the reset operation of the bit line decoder 200 in the first embodiment of the present technology.

The reset operation is an operation in which the memory cell 101 is brought to a high resistance state (HRS) to write a value “0” therein, and at this time, the bit line bl of the selected memory cell 101 is set to −4 V and the word line wl is set to 4 V.

The gbselp of the selected global bit line decoder 230 becomes −2 V, and thus the transistor 231 turns on. Accordingly, the output xb becomes the same value as the gbln. The gbln is −4 V during the reset operation.

The lbsel of the global bit line decoder 230 selected during the reset operation becomes 2 V, and thus the transistor 211 turns on. Accordingly, the output bl becomes the same value as the gbln. Therefore, −4 V is applied to the bit line bl of the memory cell 101.

Focusing on the transistor 211 of the local bit line decoder 210 here, the gate-drain voltage is 6 V. This is because the gate voltage at the time of the reset operation has been set to 2 V by using the ternary gate driver 220. In a case where the gate voltage is set to 6 V like at the time of setting, the gate-drain voltage becomes 10 V, and it becomes necessary to use a transistor having a withstand voltage of the gate-drain voltage of 10 V or more as the transistor 211. On the other hand, in this embodiment, since the gate voltage at the time of the reset operation is set to 2 V by using the ternary gate driver 220, a transistor having a withstand voltage of the gate-drain voltage of 6 V can be used as the transistor 211.

Furthermore, focusing on the amplitude of the gate voltage of the transistor 211, the gate voltage swings 6 V from −4 V to 2 V when making a transition from the non-selected state to the reset operation. On the other hand, in cases of the above-described set operation and sense operation, the gate voltage swings 10 V from −4 V to 6 V. Therefore, it can be seen that the amplitude of the gate voltage in the reset operation is smaller than that in the set operation and the sense operation. That is, by using the ternary gate driver 220 to set the gate voltage at the time of the reset operation to 2 V, the amplitude of the gate voltage at the time of the reset operation can be reduced, and the power consumption can be decreased.

Furthermore, focusing on the four transistors 231 to 234 of the global bit line decoder 230, the gate voltages of all of them have an amplitude of 6 V. This is due to the provision of four transistors, unlike the configuration with two transistors similar to the local bit line decoder 210. Thus, the power consumption is decreased, and also a transistor having a withstand voltage of 6 V of the gate-drain voltage can be used.

In this way, two methods are used to reduce the gate-drain voltage of the transistor used in the bit line decoder 200 and reduce the amplitude of the gate voltage. That is, the global bit line decoder 230 uses four transistors, and the local bit line decoder 210 uses the ternary gate driver 220. Each of these two methods can be used independently. However, in this example, it is assumed that the number of global bit line decoders 230 is 32 and the number of local bit line decoders 210 is 1024, and the number of local bit line decoders 210 is predominantly large. Therefore, if the local bit line decoder 210 has a four-transistor configuration, there may be a problem that floor area efficiency on the chip deteriorates. On the other hand, in a case where the ternary gate driver is used for the global bit line decoder 230, there may be a problem that the number of wires increases and the power consumption increases. Further, in the case of the global bit line decoder 230, since the gate inputs are independent of each other, it is conceivable that the method using four transistors requires less increase in circuit scale as compared to the method using the ternary gate driver 220. Therefore, in view of these circumstances, in a case where the 1-Mbit memory cell configuration is assumed, the configuration of the above-described embodiment is considered to be the best.

[Word Line Decoder]

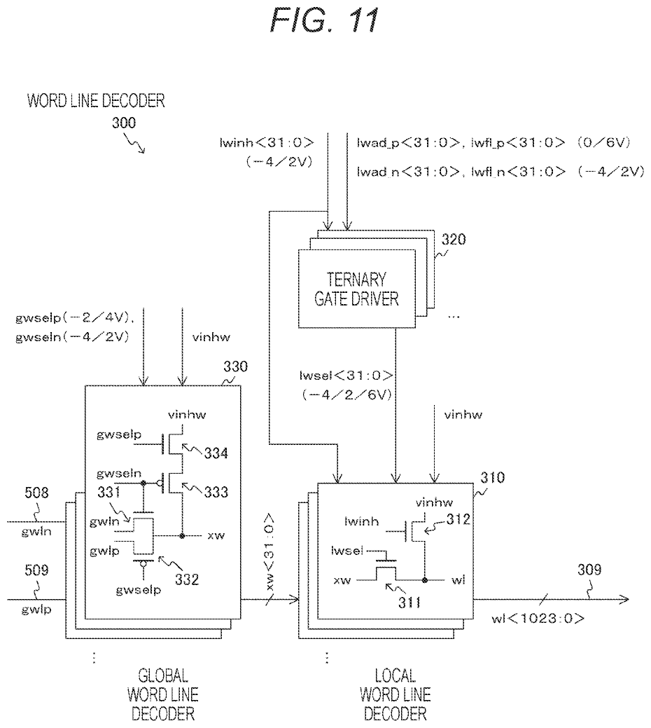

FIG. 11 is a diagram illustrating a configuration example of the word line decoder 300 in the first embodiment of the present technology.

This word line decoder 300 includes local word line decoders 310, ternary gate drivers 320, and global word line decoders 330. Note that the local word line decoders 310 are an example of the specific stage and the second specific stage described in the claims. Further, the ternary gate drivers 320 are an example of the driver described in the claims. Furthermore, the global word line decoders 330 are an example of the first specific stage described in the claims.

The local word line decoders 310 and the global word line decoders 330 are address decoders that decode the word line among the specified addresses. In this example, the local word line decoders 310 select 32 lines from 1024 lines and the global word line decoders 330 select one line from 32 lines, as in the bit line decoder 200 described above. In this case, 1024 local word line decoders 310 are needed and 32 global word line decoders 330 are needed. That is, the signal lines 309 are 1024 word line signals wl <1023:0>, and the local word line decoders 310 cause only one line to be in a selected state and the other 1023 lines to be in a non-selected state.

Each of the global word line decoders 330 includes four transistors 331 to 334, as in the global bit line decoder 230 described above. The transistor 331 is an nMOS transistor, and turns on and sets the potential of output xw to gwln when a gate signal gwseln is at H level. The transistor 332 is a pMOS transistor, and turns on and sets the potential of the output xw to gwlp when a gate signal gwselp is at L level. That is, the transistors 331 and 332 have outputs connected to each other and become exclusively conductive. As will be described later, the gwlp is a bias voltage supplied from the word line bias control circuit 500 via the signal line 509, and the gwln is a bias voltage supplied from the word line bias control circuit 500 via the signal line 508.

The transistors 333 and 334 are connected in series. The transistor 333 is a pMOS transistor and turns on when the gate signal gwseln is at L level. The transistor 334 is an nMOS transistor and turns on when the gate signal gwselp is at H level. Therefore, both the transistors 333 and 334 turn on and set the potential of the output xw to vinhw when the gwseln is at L level and the gwselp is at H level. The vinhw is a voltage indicating inhibit meaning non-selection, and is 0 V for example.

Each of the local word line decoders 310 includes two transistors 311 and 312, as in the local bit line decoder 210 described above. The transistor 311 is an nMOS transistor, and turns on and sets the potential of the output wl to the xw when a gate signal lwsel is at H level. Here, the xw is the output of the corresponding global word line decoder 330. The transistor 312 is an nMOS transistor, and turns on and sets the potential of the output wl to the vinhw when a gate signal lwinh is at H level. Therefore, the potential of the output wl becomes the output xw of the corresponding global word line decoder 330 when the lwsel is at H level, and becomes the vinhw when the lwinh is at H level.

However, the transistors 311 and 312 can be used by switching the drive voltage similarly to the above-described transistors 211 and 212. The gate voltage lwsel has any of three values of high potential, medium potential, and low potential. These gate voltages of three values are supplied by a ternary gate driver 320.

The ternary gate driver 320 supplies the gate voltage lwsel of the transistors 311 and 312 of the local word line decoder 310. In this example, it is assumed that the ternary gate driver 320 outputs one of three values of 6 V (high potential), 2 V (medium potential), and −4 V (low potential).

[Word line bias control circuit]

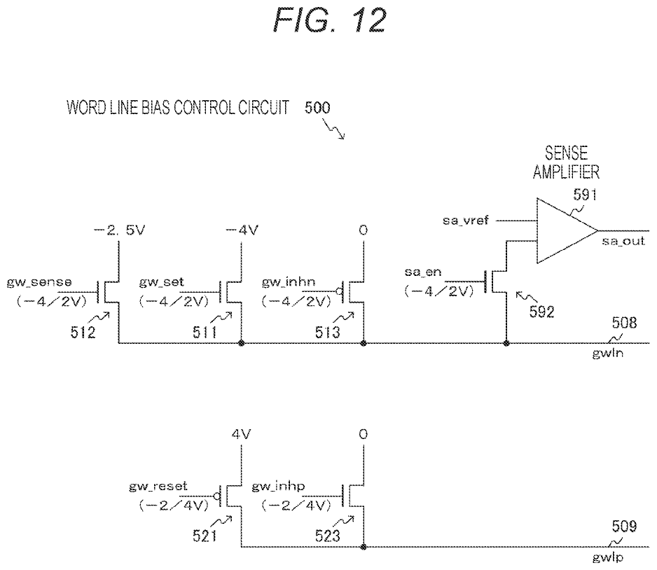

FIG. 12 is a diagram illustrating a configuration example of the word line bias control circuit 500 in the first embodiment of the present technology.

The word line bias control circuit 500 includes six transistors 511 to 513, 521, 523, and 592, and a sense amplifier 591.

The transistor 511 is an nMOS transistor and turns on when a gate signal gw_set is at H level. In this example, it turns on and sets the bias voltage gwln of the signal line 508 to −4 V when the gw_set is 2 V. That is, the bias voltage gwln of −4 V is supplied for set operation.

The transistor 512 is an nMOS transistor and turns on when a gate signal gw_sense is at H level. In this example, it turns on and sets the bias voltage gwln of the signal line 508 to −2.5 V when the gw_sense is 2 V. That is, the bias voltage gwln of −2.5 V is supplied for sense operation.

The transistor 513 is a pMOS transistor and turns on when a gate signal gw_inhn is at L level. In this example, it turns on and sets the bias voltage gwln of the signal line 508 to 0 V when the gw_inhn is −4 V. That is, the bias voltage gbln of 0 V is supplied for non-selective operation.

The transistor 521 is a pMOS transistor and turns on when a gate signal gw_reset is at L level. In this example, it turns on and sets the bias voltage gwlp of the signal line 509 to 4 V when the gw_reset is −2 V. That is, the bias voltage gwlp of 4 V is supplied for reset operation.

The transistor 523 is an nMOS transistor and turns on when a gate signal gw_inhp is at H level. In this example, it turns on and sets the bias voltage gwlp of the signal line 509 to 0 V when the gw_inhp is 4 V. That is, the bias voltage gblp of 0 V is supplied for non-selective operation.

The sense amplifier 591 is a sense amplifier that amplifies the voltage gwln of the signal line 508 with reference to a signal sa_vref and outputs it to sa_out. The transistor 592 is connected to one input of the sense amplifier 591. The transistor 592 is an nMOS transistor, and turns on and inputs the voltage gwln of the signal line 508 to the sense amplifier 591 when a gate signal sa_en is at H level. Note that the sense amplifier 591 is provided on the word line side because it is considered that there is smaller parasitic capacitance than that on the bit line side.

Thus, the gate voltage of the transistors 511 to 513 and 592 is −4 V or 2 V, having an amplitude of 6 V. Furthermore, the gate voltage of the transistors 521 and 523 is −2 V or 4 V, having an amplitude of 6 V.

[Ternary Gate Driver]

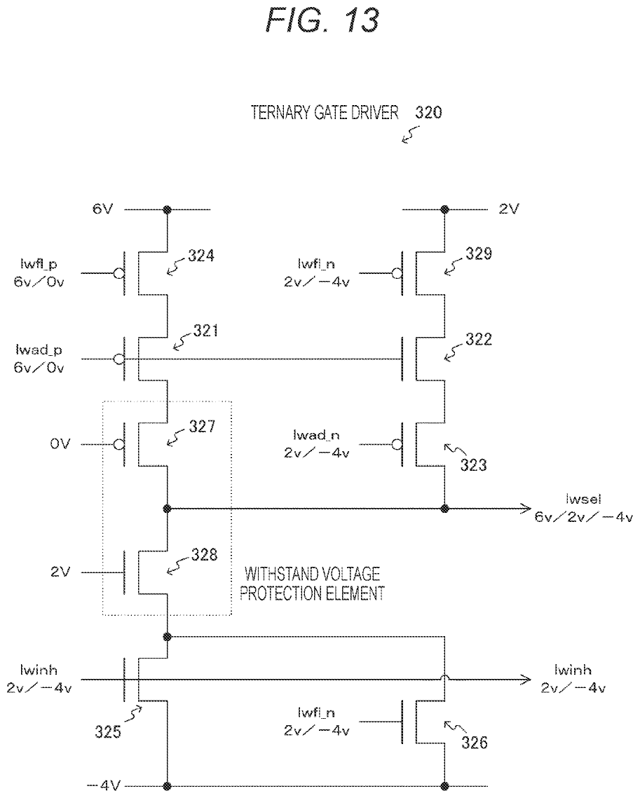

FIG. 13 is a diagram illustrating a configuration example of the ternary gate driver 320 in the embodiment of the present technology.

The ternary gate driver 320 includes nine transistors 321 to 329.

The transistor 321 is a pMOS transistor and turns on when a gate signal lwad_p is at L level. The transistor 322 is an nMOS transistor and turns on when the gate signal lwad_p is at H level. The transistor 323 is a pMOS transistor and turns on when a gate signal lwad_n is at L level. The transistor 325 is an nMOS transistor and turns on when the gate signal lwinh is at H level.

The transistor 324 is a pMOS transistor and turns on when a gate signal lwfl_p is at L level. The transistor 329 is a pMOS transistor and turns on when a gate signal lwfl_n is at H level. The transistor 326 is an nMOS transistor and turns on when the gate signal lwfl_n is at H level.

The gate voltage of the transistors 321, 322, and 324 is 0 V or 6 V, having an amplitude of 6 V. Furthermore, the gate voltage of transistors 323, 325, 326, and 329 is −4 V or 2 V, having an amplitude of 6 V.

The transistor 327 is a pMOS transistor, and 0 V is fixedly input as a gate signal. The transistor 328 is an nMOS transistor, and 2 V is fixedly input as a gate signal. These transistors 327 and 328 are withstand voltage protection elements similar to the above-described transistors 227 and 228.

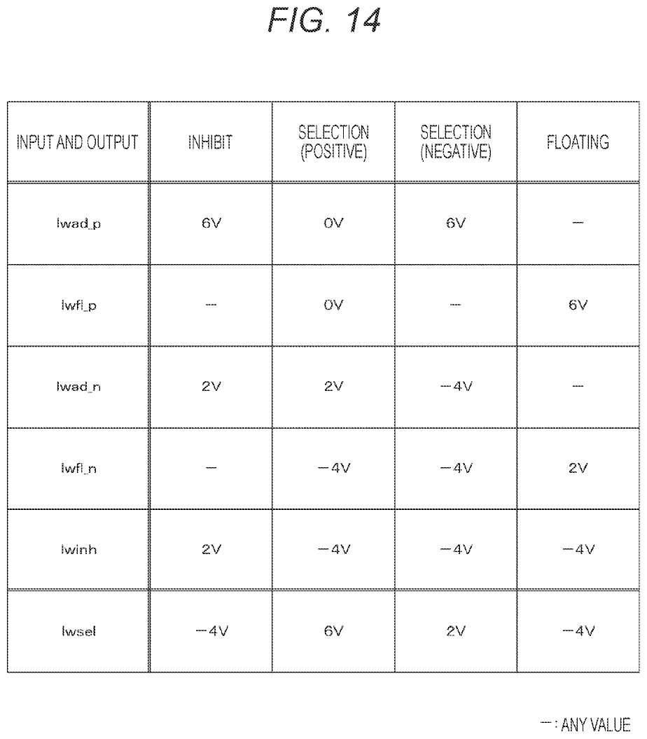

FIG. 14 is a diagram illustrating an example of a truth table of the ternary gate driver 320 in the embodiment of the present technology.

The ternary gate driver 320 supplies a potential of any of selection (positive), selection (negative), inhibit, and floating according to the lwad_p, lwfl_p, lwad_n, lwfl_n, and lwinh as the gate voltage lwsel of the transistor 311 of the local word line decoder 310. In this example, the selection (positive) is a voltage for reset operation and is 6 V (high potential). Furthermore, the selection (negative) is a voltage for set operation or sense operation and is 2 V (medium potential). The inhibit is a voltage for non-selective operation and is −4 V (low potential).

Furthermore, the floating is a voltage for setting to high impedance and is −4 V (low potential), which is the same as the inhibit. This floating is provided because it is necessary to cause a temporarily transition of the word line to floating at the time of reading. That is, by applying a voltage to the bit line while the word line is in a floating state, a selected voltage is applied to the memory cell 101 and reading is performed.

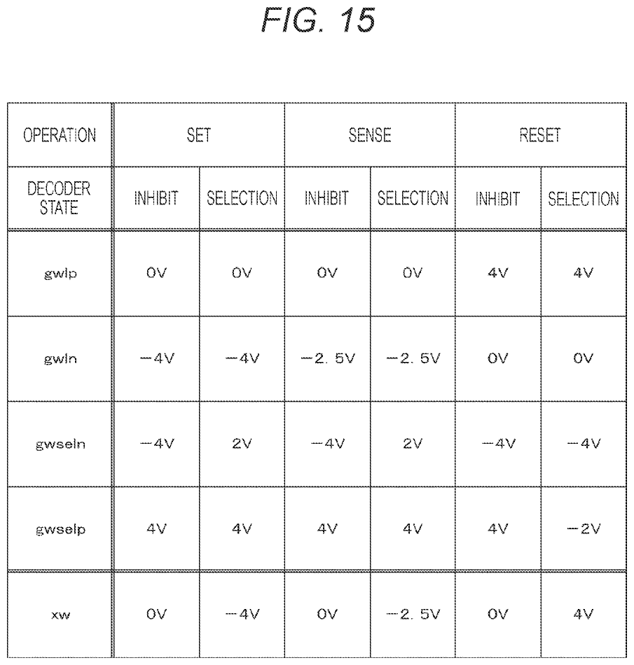

FIG. 15 is a diagram illustrating an example of a truth table of the global word line decoder 330 in the first embodiment of the present technology. Details of each operation will be described below.

[Voltage in Word Line Decoder]

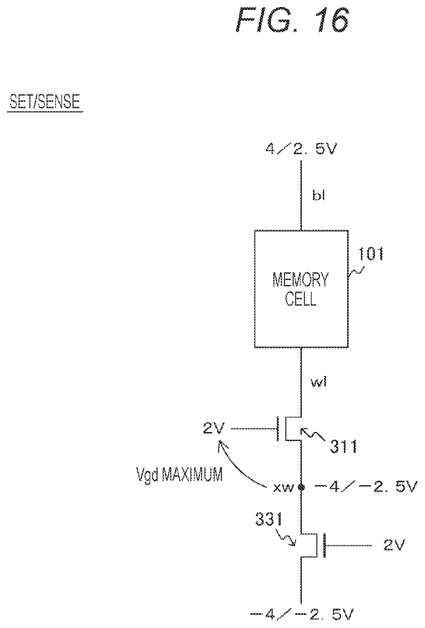

FIG. 16 is a diagram illustrating an example of a voltage state of set operation or sense operation of the word line decoder 300 in the first embodiment of the present technology.

The gwseln of the selected global word line decoder 330 becomes 2 V, and thus the transistor 331 turns on. Accordingly, the output xw becomes the same value as the gwln. During the set operation, the gwln is −4 V, and during the sense operation, the gwln is −2.5 V.

The lwsel of the local word line decoder 310 selected during the set operation or the sense operation becomes 2 V, and thus the transistor 311 turns on. Accordingly, the output wl becomes the same value as the gwln. Therefore, to the word line wl of the memory cell 101, −4 V is applied during the set operation, and −2.5 V is applied during the sense operation.

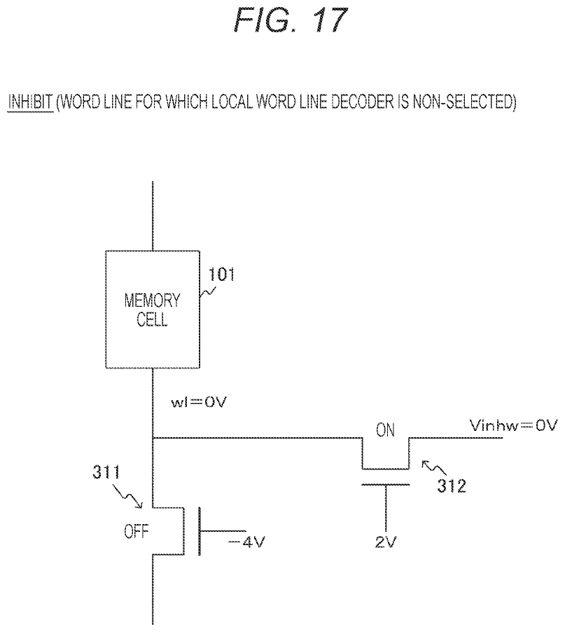

FIG. 17 is a diagram illustrating a first example of a voltage state of the non-selective operation of the word line decoder 300 in the first embodiment of the present technology.

Here, a word line for which the local word line decoder 310 is non-selected is assumed. In this case, the lwsel becomes −4 V (low potential), and thus the transistor 311 turns off. On the other hand, the lwinh becomes 2 V, and thus the transistor 312 turns on. Accordingly, the output wl becomes 0 V, which is the same as the vinhw. That is, the memory cell 101 becomes a non-selected state.

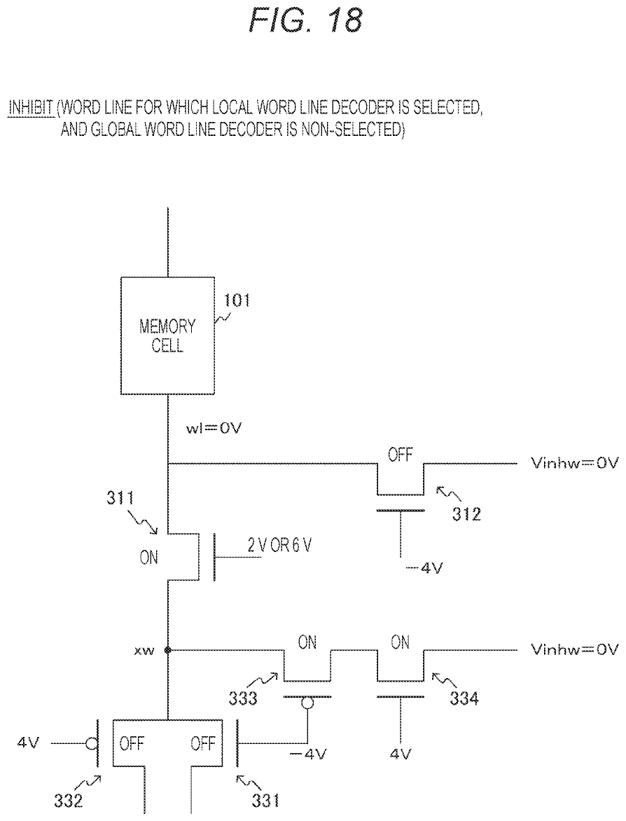

FIG. 18 is a diagram illustrating a second example of a voltage state of the non-selective operation of the word line decoder 300 in the first embodiment of the present technology.

Here, a word line for which the local word line decoder 310 is selected and the global word line decoder 330 is non-selected is assumed. In this case, the gwselp is 4 V and the gwseln is −4 V. Thus, the transistors 331 and 332 turn off, and the transistors 333 and 334 turn on. Accordingly, the output xw becomes 0 V, which is the same as the vinhw.

Furthermore, in this case, the lwsel becomes 6 V (high potential) or 2 V (medium potential). Thus, the transistor 311 turns on. On the other hand, the lwinh becomes −4 V, and thus the transistor 312 turns off. Accordingly, the output wl becomes 0 V, which is the same as the xw. That is, the memory cell 101 becomes a non-selected state.

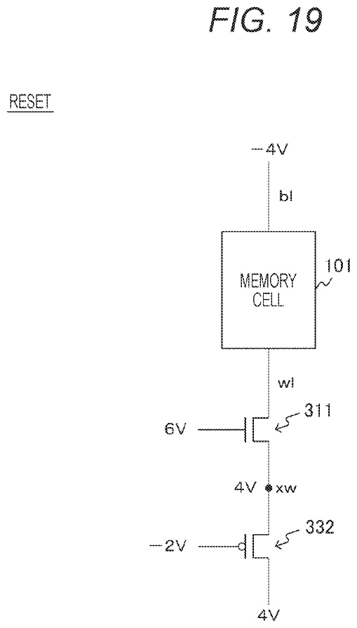

FIG. 19 is a diagram illustrating an example of a voltage state of the reset operation of the word line decoder 300 in the first embodiment of the present technology.

The gwselp of the selected global word line decoder 330 becomes −2 V, and thus the transistor 332 turns on. Accordingly, the output xw becomes the same value as the gwlp. The gwlp is 4 V during the reset operation.

The lwsel of the local word line decoder 310 selected during the reset operation becomes 6 V, and thus the transistor 311 turns on. Accordingly, the output wl becomes the same value as the gwlp. Therefore, 4 V is applied to the word line wl of the memory cell 101.

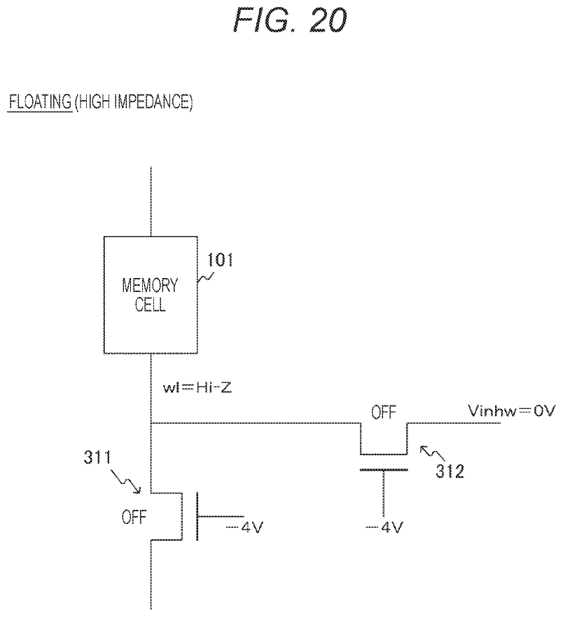

FIG. 20 is a diagram illustrating an example of a voltage state of the floating operation of the word line decoder 300 in the first embodiment of the present technology.

In this case, the lwsel becomes −4 V (low potential), and thus the transistor 311 turns off. On the other hand, the lwinh becomes −4 V, and thus the transistor 312 also turns off. Accordingly, the output wl is not connected to any of them, thereby having high impedance. That is, the memory cell 101 is brought into a floating state.

Here, the voltage of the transistor 311 of the local word line decoder 310 will be examined. The gate-drain voltage of the transistor 311 at the time of set operation is 6 V. This is because the gate voltage at the time of the set operation has been set to 2 V by using the ternary gate driver 220. In a case where the gate voltage is set to 6 V like at the time of resetting, the gate-drain voltage becomes 10 V, and it becomes necessary to use a transistor having a withstand voltage of the gate-drain voltage of 10 V or more as the transistor 311. On the other hand, in this embodiment, since the gate voltage at the time of the set operation is set to 2 V by using the ternary gate driver 320, a transistor having a withstand voltage of the gate-drain voltage of 6 V can be used as the transistor 311.

Furthermore, focusing on the amplitude of the gate voltage of the transistor 311, the gate voltage swings 6 V from −4 V to 2 V when making a transition from the non-selected state to the set operation or the sense operation. On the other hand, in a case of the reset operation, the gate voltage swings 10 V from −4 V to 6 V. Therefore, it can be seen that the amplitude of the gate voltage in the set operation or the sense operation is smaller as compared to that in the reset operation. That is, by using the ternary gate driver 320 to set the gate voltage at the time of the set operation or the sense operation to 2 V, the amplitude of the gate voltage can be reduced and the power consumption can be decreased.

Furthermore, focusing on the four transistors 331 to 334 of the global word line decoder 330, all of these gate voltages have an amplitude of 6 V. This is due to the provision of four transistors, unlike the configuration with two transistors similar to the local word line decoder 310. Thus, the power consumption is decreased, and also a transistor having a withstand voltage of 6 V of the gate-drain voltage can be used.

In this way, two methods are used to reduce the gate-drain voltage of the transistor used in the word line decoder 300 and reduce the amplitude of the gate voltage. In this respect, the trade-off with respect to which method is used is similar to that described for the above-mentioned bit line decoder 200.

### Modification Example

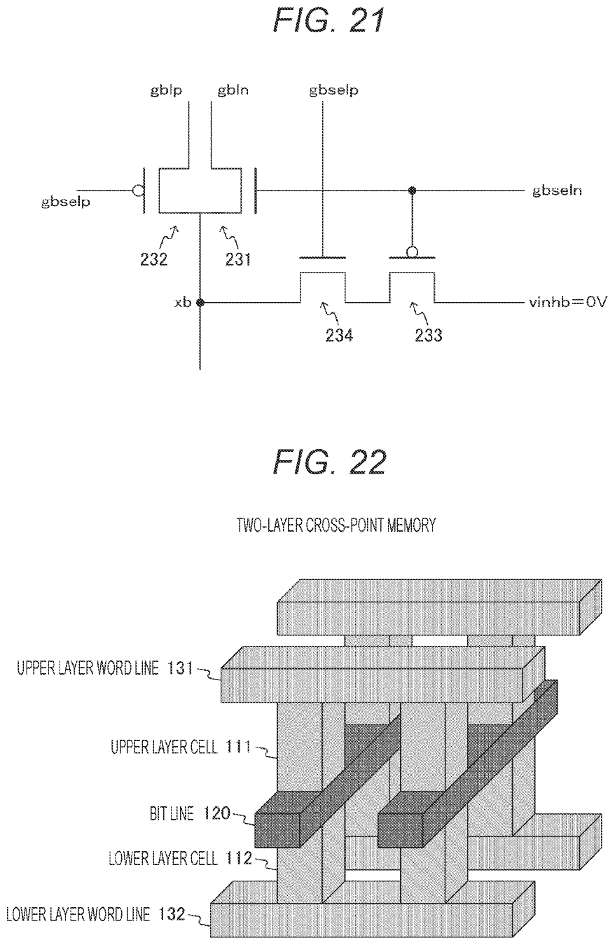

FIG. 21 is a diagram illustrating a modification example of the global bit line decoder 230 in the first embodiment of the present technology.

This modification example of the global bit line decoder 230 is a modification in which the order of connection of the transistors 233 and 234 is replaced. That is, in the inhibit operation, when the gbseln is at L level and the gbselp is at H level, both the transistors 233 and 234 turn on and the potential of the output xb is set to the vinhb, and thus the order of connection may be any order.

Note that the same applies to the order of connection of the transistors 333 and 334 of the global word line decoder 330.

As described above, according to the first embodiment of the present technology, it is possible to reduce the withstand voltage of the gate-drain voltage of the transistors constituting the decoder and also reduce the amplitude of the gate voltage, and the power consumption can be decreased. The area of the transistor is proportional to the square of the withstand voltage. Furthermore, the power consumption of the circuit is proportional to the square of the amplitude. Therefore, by using a transistor having a lower withstand voltage and reducing the voltage amplitude, it is possible to simultaneously achieve a reduction in bit cost and a reduction in power consumption.

### 2. Second Embodiment

In the first embodiment described above, it is assumed that 1-Mbit memory cells are arranged, but when the array scale is larger than this, it is considered that a structure in which memory cells are stacked in two layers is suitable. In this second embodiment, an example of application to a two-layer cross-point memory will be described. Note that the overall configuration is similar to that of the first embodiment described above, and thus detailed description thereof will be omitted.

[Memory Array]

FIG. 22 is a diagram illustrating a structural example of a cross-point memory array 100 in the second embodiment of the present technology.

A cross-point memory array 100 in the second embodiment has a two-layer structure in which an upper layer cell 111 and a lower layer cell 112 share a bit line 120. An upper layer word line 131 and a lower layer word line 132, which are respective word lines, are arranged on opposite sides via the bit line 120. A point that the memory cells (upper layer cells 111 and lower layer cells 112 in this example) are arranged at intersections of upper layer word lines 131 and lower layer word lines 132 and bit lines 120 is similar to the first embodiment described above.

Since a structure in which the upper layer cell 111 and the lower layer cell 112 share the bit line 120 is assumed in this way, the polarities of the upper layer cell 111 and the lower layer cell 112 are different. That is, assuming that a current flows from an upper terminal to a lower terminal during the set operation or the sense operation and a current flows from the lower terminal to the upper terminal during the reset operation, the upper terminal in the upper layer cell 111 corresponds to the upper layer word line 131. Therefore, the direction of the current during the set operation or the sense operation of the upper layer cell 111 is the direction from the upper layer word line 131 to the bit line 120, and the upper layer word line 131 is on the high voltage side.

On the other hand, the upper terminal in the lower layer cell 112 corresponds to the bit line 120. Therefore, the direction of the current during the set operation or the sense operation of the lower layer cell 112 is the direction from the bit line 120 to the lower layer word line 132, and the bit line 120 is on the high voltage side.

Thus, for example, in the truth tables of the ternary gate drivers 220 and 320, the upper layer cell 111 is similar to that of the first embodiment described above, but the lower layer cell 112 has the opposite polarity. That is, for the lower layer cell 112, in a case of the ternary gate driver 220, the selection (positive) is a voltage for reset operation. Further, the selection (negative) is a voltage for the set operation or sense operation. Furthermore, in a case of the ternary gate driver 320, the selection (positive) is a voltage for the set operation or sense operation. Further, the selection (negative) is a voltage for the reset operation.

[Bit Line Decoder]

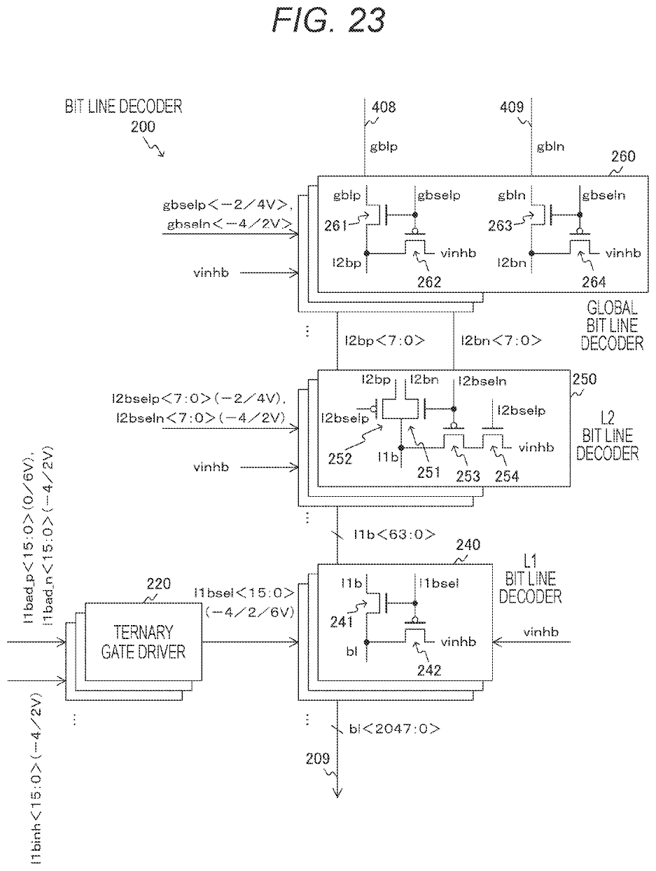

FIG. 23 is a diagram illustrating a configuration example of a bit line decoder 200 in the second embodiment of the present technology.

The bit line decoder 200 of the second embodiment includes an L1 bit line decoder 240, an L2 bit line decoder 250, a ternary gate driver 220, and a global bit line decoder 260. That is, the bit line decoder 200 in the first embodiment described above performs decoding in two stages, but in this second embodiment, decoding is performed in three stages. Note that the L1 bit line decoder 240 is an example of the specific stage and the second specific stage described in the claims. Furthermore, the L2 bit line decoder 250 is an example of the first specific stage described in the claims.

In this example, the L1 bit line decoder 240 selects 64 lines from 2048 lines, the L2 bit line decoder 250 selects eight lines from 64 lines, and the global bit line decoder 260 selects one line from eight lines.

Each of the global bit line decoders 260 includes four transistors 261 to 264. The transistor 261 is an nMOS transistor, and turns on and sets the potential of output 12bp to the gblp when the gate signal gbselp is at H level. The gblp is the bias voltage supplied from the bit line bias control circuit 400 via the signal line 408. The transistor 262 is a pMOS transistor, and turns on and sets the potential of the output 12bp to the vinhb when the gate signal gbselp is at L level.

The transistor 263 is an nMOS transistor, and turns on and sets the potential of output 12bn to the gbln when the gate signal gbseln is at H level. The gbln is the bias voltage supplied from the bit line bias control circuit 400 via the signal line 409. The transistor 264 is a pMOS transistor, and turns on and sets the potential of the output 12bn to the vinhb when the gate signal gbseln is at L level.

Each of the L2 bit line decoders 250 includes four transistors 251 to 254. The transistor 251 is an nMOS transistor, and turns on and sets the potential of output lib to the 12bn when a gate signal l2bseln is at H level. The transistor 252 is a pMOS transistor, and turns on and sets the potential of the output lib to the 12bp when a gate signal 12bselp is at L level. That is, the transistors 251 and 252 have outputs connected to each other and become exclusively conductive.

The transistors 253 and 254 are connected in series. The transistor 253 is a pMOS transistor and turns on when the gate signal l2bseln is at L level. The transistor 254 is an nMOS transistor and turns on when the gate signal 12bselp is at H level. Therefore, when the l2bseln is at L level and the 12bselp is at H level, both the transistors 253 and 254 turn on to bring the potential of the output lib to the vinhb.

Each of the L1 bit line decoders 240 includes two transistors 241 and 242. The transistor 241 is an nMOS transistor, and turns on and sets the potential of output bl to the lib when a gate signal l1bsel is at H level. The transistor 252 is a pMOS transistor, and turns on and sets the potential of the output bl to the vinhb when the gate signal l1bsel is at L level. Therefore, the potential of the output bl becomes the output lib of the corresponding L2 bit line decoder 250 when the l1bsel is at H level, and becomes the vinhb when the l1bsel is at L level.

The ternary gate driver 220 is similar to that of the first embodiment described above, and supplies the gate voltage l1bsel of the transistors 241 and 242 of the L1 bit line decoder 240, and outputs one of three values of 6 V (high potential), 2 V (medium potential), and −4 V (low potential).

[Bit Line Bias Control Circuit]

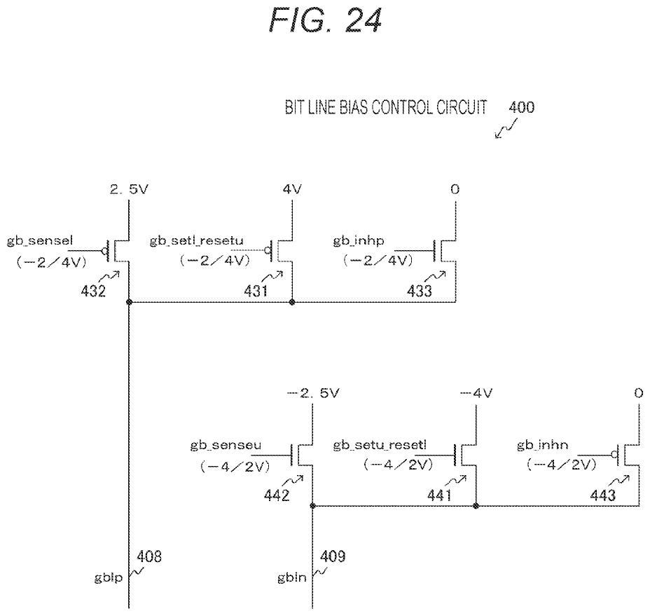

FIG. 24 is a diagram illustrating a configuration example of a bit line bias control circuit 400 in the second embodiment of the present technology.

The bit line bias control circuit 400 of this second embodiment includes six transistors 431 to 433 and 441 to 443.

The transistor 431 is a pMOS transistor and turns on when a gate signal gb_setl_resetu is at L level. In this example, it turns on and sets the bias voltage gblp of the signal line 408 to 4 V when the gb_setl_resetu is −2 V. That is, the bias voltage gblp of 4 V is supplied for the lower layer cell 112 to perform the set operation or for the upper layer cell 111 to perform the reset operation.

The transistor 432 is a pMOS transistor and turns on when a gate signal gb_sensel is at L level. In this example, it turns on and sets the bias voltage gblp of the signal line 408 to 2.5 V when the gb_sensel is −2 V. That is, the bias voltage gblp of 2.5 V is supplied for the lower layer cell 112 to perform the sense operation.

The transistor 433 is an nMOS transistor and turns on when the gate signal gb_inhp is at H level. In this example, it turns on and sets the bias voltage gblp of the signal line 408 to 0 V when the gb_inhp is 4 V. That is, the bias voltage gblp of 0 V is supplied for non-selective operation.

The transistor 441 is an nMOS transistor and turns on when a gate signal gb_setu_resetl is at H level. In this example, it turns on and sets the bias voltage gbln of the signal line 409 to −4 V when the gb_setu_resetl is 2 V. That is, the bias voltage gbln of −4 V is supplied for the upper layer cell 111 to perform the set operation or for the lower layer cell 112 to perform the reset operation.

The transistor 442 is an nMOS transistor and turns on when a gate signal gb_senseu is at H level. In this example, it turns on and sets the bias voltage gbln of the signal line 409 to −2.5 V when the gb_senseu is 2 V. That is, the bias voltage gbln of −2.5 V is supplied for the upper layer cell 111 to perform the sense operation.

The transistor 443 is a pMOS transistor and turns on when the gate signal gb_inhn is at L level. In this example, it turns on and sets the bias voltage gbln of the signal line 409 to 0 V when the gb_inhn is −4 V. That is, the bias voltage gbln of 0 V is supplied for non-selective operation.

Thus, the gate voltage of the transistors 431 to 433 is −2 V or 4 V, having an amplitude of 6 V. Furthermore, the gate voltage of the transistors 441 to 443 is −4 V or 2 V, having an amplitude of 6 V.

[Word Line Decoder]

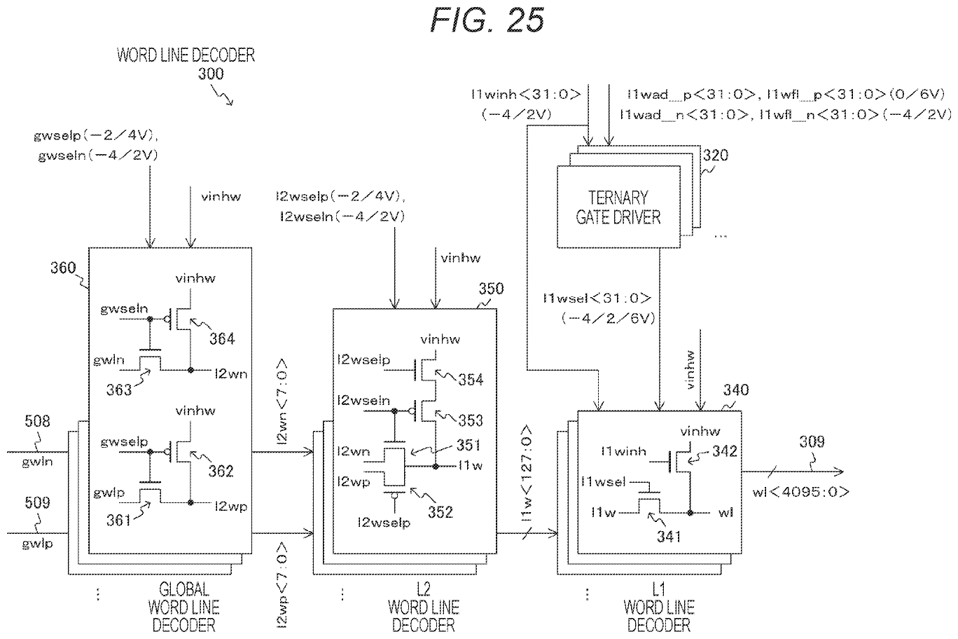

FIG. 25 is a diagram illustrating a configuration example of the word line decoder 300 in the second embodiment of the present technology.

The word line decoder 300 of the second embodiment includes L1 word line decoders 340, L2 word line decoders 350, ternary gate drivers 320, and global word line decoders 360. That is, the word line decoder 300 in the first embodiment described above performs decoding in two stages, but in this second embodiment, decoding is performed in three stages. Note that the L1 word line decoders 340 are an example of the specific stage and the second specific stage described in the claims. Furthermore, the L2 word line decoders 350 are an example of the first specific stage described in the claims.

In this example, the L1 word line decoders 340 select 128 lines from 4096 lines, the L2 word line decoders 350 select eight lines from 128 lines, and the global word line decoders 360 select one line from eight lines.

Each of the global word line decoders 360 includes four transistors 361 to 364. The transistor 361 is an nMOS transistor, and turns on and sets the potential of output 12wp to the gwlp when the gate signal gwselp is at H level. The gwlp is the bias voltage supplied from the word line bias control circuit 500 via the signal line 509. The transistor 362 is a pMOS transistor, and turns on and sets the potential of the output 12wp to the vinhw when the gate signal gwselp is at L level.

The transistor 363 is an nMOS transistor, and turns on and sets the potential of output 12wn to the gwln when the gate signal gwseln is at H level. The gwln is the bias voltage supplied from the word line bias control circuit 500 via the signal line 508. The transistor 364 is a pMOS transistor, and turns on and sets the potential of the output 12wn to the vinhw when the gate signal gwseln is at L level.

Each of the L2 word line decoders 350 includes four transistors 351 to 354. The transistor 351 is an nMOS transistor, and turns on and sets the potential of output 11w to the 12wn when a gate signal 12wseln is at H level. The transistor 352 is a pMOS transistor, and turns on and sets the potential of the output 11w to the 12wp when the gate signal 12wselp is at L level. That is, the transistors 351 and 352 have outputs connected to each other and become exclusively conductive.

The transistors 353 and 354 are connected in series. The transistor 353 is a pMOS transistor and turns on when the gate signal 12wseln is at L level. The transistor 354 is an nMOS transistor and turns on when the gate signal 12wselp is at H level. Therefore, when l2wseln is at L level and 12wselp is at H level, both the transistors 353 and 354 turn on to bring the potential of the output 11w to the vinhw.

Each of the L1 word line decoders 340 includes two transistors 341 and 342. The transistor 341 is an nMOS transistor, and turns on and sets the potential of output wl to 11w when the gate signal l1wsel is at H level. The transistor 342 is an nMOS transistor, and turns on and sets the potential of the output wl to the vinhw when the gate signal l1winh is at H level. Therefore, the potential of the output wl becomes the output 11w of the corresponding L2 word line decoder 350 when l1wsel is at H level, and becomes the vinhw when l1winh is at H level.

The ternary gate driver 220 is similar to that of the first embodiment described above and supplies the gate voltage l1wsel of the transistor 341 of the L1 word line decoder 340, and outputs one of three values of 6 V (high potential), 2 V (medium potential), and −4 V (low potential).

[Word Line Bias Control Circuit]

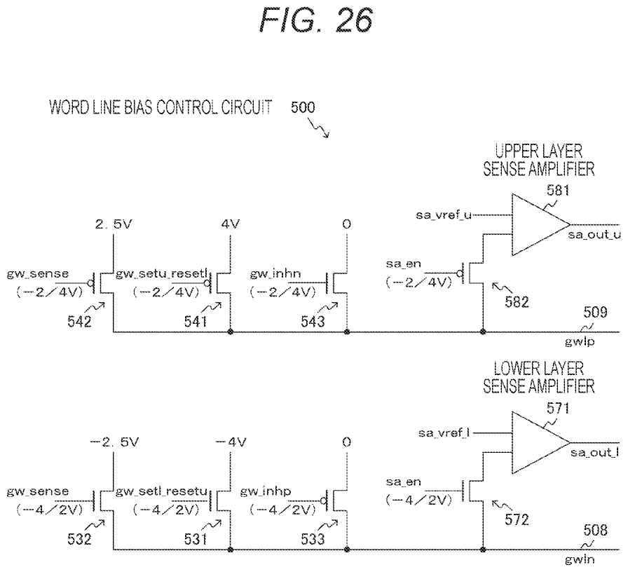

FIG. 26 is a diagram illustrating a configuration example of a word line bias control circuit 500 in the second embodiment of the present technology.

The word line bias control circuit 500 includes eight transistors 531 to 533, 541 to 543, 572, and 582, and sense amplifiers 571 and 581.

The transistor 531 is an nMOS transistor and turns on when a gate signal gw_setl_resetu is at H level. In this example, it turns on and sets the bias voltage gwln of the signal line 508 to −4 V when the gw_setl_resetu is 2 V. That is, the bias voltage gwln of −4 V is supplied for the lower layer cell 112 to perform the set operation or for the upper layer cell 111 to perform the reset operation.

The transistor 532 is an nMOS transistor and turns on when the gate signal gw_sense is at H level. In this example, it turns on and sets the bias voltage gwln of the signal line 508 to −2.5 V when the gw_sense is 2 V. That is, the bias voltage gwln of −2.5 V is supplied to perform the sense operation.

The transistor 533 is a pMOS transistor and turns on when the gate signal gw_inhp is at L level. In this example, it turns on and sets the bias voltage gwln of the signal line 508 to 0 V when the gw_inhp is −4 V. That is, the bias voltage gwln of 0 V is supplied for non-selective operation.

The transistor 541 is a pMOS transistor and turns on when a gate signal gw_setu_resetl is at L level. In this example, it turns on and sets the bias voltage gwlp of the signal line 509 to 4 V when the gw_setu_resetl is −2 V. That is, the bias voltage gwlp of 4 V is supplied for the upper layer cell 111 to perform the set operation or for the lower layer cell 112 to perform the reset operation.

The transistor 542 is a pMOS transistor and turns on when the gate signal gw_sense is at L level. In this example, it turns on and sets the bias voltage gwlp of the signal line 509 to 2.5 V when the gw_sense is −2 V. That is, the bias voltage gwlp of 2.5 V is supplied to perform the sense operation.

The transistor 543 is an nMOS transistor and turns on when the gate signal gw_inhn is at H level. In this example, it turns on and sets the bias voltage gwlp of the signal line 509 to 0 V when the gw_inhn is 4 V. That is, the bias voltage gwlp of 0 V is supplied for non-selective operation.

The upper layer sense amplifier 581 is a sense amplifier of the upper layer cell 111 that amplifies the voltage gwlp of the signal line 509 with reference to the signal as_vref_u and outputs it to sa_out_u. The transistor 582 is connected to one input of the upper layer sense amplifier 581. The transistor 582 is a pMOS transistor, and turns on and inputs the voltage gwlp of the signal line 509 to the upper layer sense amplifier 581 when the gate signal sa_en is at L level (−2 V). In this way, the upper layer sense amplifier 581 senses a positive voltage gwlp.

The lower layer sense amplifier 571 is a sense amplifier of the lower layer cell 112 that amplifies the voltage gwln of the signal line 508 with reference to a signal as_vref_l and outputs it to sa_out_l. The transistor 572 is connected to one input of the lower layer sense amplifier 571. The transistor 572 is an nMOS transistor, and turns on and inputs the voltage gwln of the signal line 508 to the lower layer sense amplifier 571 when the gate signal sa_en is at H level (2 V). In this way, the lower layer sense amplifier 571 senses the negative voltage gwln.

Thus, the gate voltage of the transistors 531 to 533 and 572 is −4 V or 2 V, having an amplitude of 6 V. Furthermore, the gate voltage of the transistors 541 to 543 and 582 is −2 V or 4 V, having an amplitude of 6 V.

In this second embodiment, the bit line decoder 200 and the word line decoder 300 each have a three-stage configuration. Then, each of the L2 bit line decoder 250 and the L2 word line decoder 350 in the middle stage includes four transistors. Furthermore, each of the lower L1 bit line decoder 240 and the L1 word line decoder 340 includes two transistors, and gate voltages of three values are supplied from the ternary gate drivers 220 and 320. These are for lowering the gate-drain voltage of the transistors used in the bit line decoder 200 and the word line decoder 300 and reducing the amplitude of the gate voltage, as in the first embodiment described above.

Which of the two methods is used can be determined as in the first embodiment described above. That is, the number of L1 bit line decoders 240 is 2048, and the number of L1 word line decoders 340 is 4096, which is predominantly large. Therefore, it is better to use a ternary gate driver than to have a four-transistor configuration.

Furthermore, if the L2 bit line decoder 250 and the L2 word line decoder 350 have a four-transistor configuration, not only the gate-drain voltage of the transistors in them is lowered, but also a similar effect can be obtained in the global bit line decoder 260 and the global word line decoder 360 in a higher layer than them. Therefore, in the global bit line decoder 260 and the global word line decoder 360, two transistors are provided on the positive side and the negative side, respectively.

As described above, according to the second embodiment of the present technology, in the two-layer cross-point memory, it is possible to reduce the withstand voltage of the gate-drain voltage of the transistors constituting the decoder and also reduce the amplitude of the gate voltage, and the power consumption can be decreased.

Note that the embodiments described above illustrate an example for embodying the present technology, and matters in the embodiments and matters specifying the invention in the claims have respective correspondence relationships. Similarly, the matters specifying the invention in the claims and matters having the same names in the embodiments of the present technology have respective correspondence relationships.

However, the present technology is not limited to the embodiments and can be embodied by making various modifications to the embodiments without departing from the gist thereof.

Note that effects described in the present description are merely examples and are not limited, and other effects may be provided.

Note that the present technology can have configurations as follows.

(1) A memory control circuit including a plurality of stages of memory decoders configured to select a specific cell of a memory according to a specified address and apply a predetermined voltage to two ends of the specific cell,

in which a first specific stage that is at least one of the plurality of stages includes:

a first transistor and a second transistor each provided according to a value to be written to the specific cell; and

a third transistor and a fourth transistor that bring the specific cell into a non-selected state.

(2) The memory control circuit according to (1) above, in which

the first and second transistors have outputs connected to each other and become exclusively conductive.

(3) The memory control circuit according to (1) or (2) above, in which

the first transistor becomes conductive either when writing a first value to the specific cell or when reading a value from the specific cell, and

the second transistor becomes conductive when writing a second value to the specific cell.

(4) The memory control circuit according to any one of (1) to (3) above, in which

the third and fourth transistors are connected in series, and when bringing the specific cell into the non-selected state, the third and fourth transistors become conductive and apply a voltage to a non-selection line.

(5) The memory control circuit according to any one of (1) to (4) above, in which

a maximum value of a gate-to-diffusion region voltage of the first to fourth transistors is smaller than the voltage applied to the two ends of the specific cell.

(6) The memory control circuit according to any one of (1) to (5) above, in which

a maximum amplitude of a gate voltage of the first to fourth transistors is smaller than the voltage applied to the two ends of the specific cell.

(7) The memory control circuit according to any one of (1) to (6) above, in which

a second specific stage that is at least one stage of the memory decoders other than the first specific stage includes:

a driver that generates voltages with three values; and

a fifth transistor and a sixth transistor that become exclusively conductive according to an output of the driver.

(8) The memory control circuit according to (7) above, in which

the fifth transistor becomes conductive by a highest voltage among the three values either when writing the first value to the specific cell or when reading a value from the specific cell, and becomes conductive by an intermediate voltage of the three values when writing the second value to the specific cell.

(9) The memory control circuit according to (7) or (8) above, in which

when bringing the specific cell into the non-selected state, the sixth transistor becomes conductive and applies a voltage to a non-selection line.

(10) The memory control circuit according to (7) or (8) above, in which

in a case where the memory decoder above the second specific stage is in a non-selected state, the fifth transistor becomes conductive and applies a voltage to a non-selection line.

(11) The memory control circuit according to any one of (7) to (10) above, in which

the second specific stage is arranged on a side of the memory with respect to the first specific stage.

(12) The memory control circuit according to any one of (1) to (11) above, in which

the memory is a cross-point memory,

the specific cell is arranged at an intersection of a bit line and a word line, and

the plurality of stages of the memory decoders is provided for each of the bit line and the word line.

(13) A memory control circuit including a plurality of stages of memory decoders configured to select a specific cell of a memory according to a specified address and apply a predetermined voltage to two ends of the specific cell,

in which a specific stage that is at least one of the plurality of stages includes:

a driver that generates voltages with three values; and

a first transistor and a second transistor that become exclusively conductive according to an output of the driver.

(14) The memory control circuit according to (13) above, in which

the first transistor becomes conductive by a highest voltage among the three values either when writing a first value to the specific cell or when reading a value from the specific cell, and becomes conductive by an intermediate voltage of the three values when writing a second value to the specific cell.

(15) The memory control circuit according to (13) or (14) above, in which

when bringing the specific cell into a non-selected state, the second transistor becomes conductive and applies a voltage to a non-selection line.

(16) The memory control circuit according to (13) or (14) above, in which

in a case where the memory decoder above the specific stage is in a non-selected state, the first transistor becomes conductive and applies a voltage to a non-selection line.

(17) The memory control circuit according to any one of (13) to (16) above, in which

a maximum value of a gate-to-diffusion region voltage of the first and second transistors is smaller than the voltage applied to the two ends of the specific cell.

(18) The memory control circuit according to any one of (13) to (17) above, in which

a maximum amplitude of a gate voltage of the first and second transistors is smaller than the voltage applied to the two ends of the specific cell.

### REFERENCE SIGNS LIST

100 Cross-point memory array
101 Memory cell
111 Upper layer cell
112 Lower layer cell
120 Bit line
131 Upper layer word line
132 Lower layer word line
200 Bit line decoder
210 Local bit line decoder
220 Ternary gate driver
230 Global bit line decoder
240 L1 bit line decoder
250 L2 bit line decoder
260 Global bit line decoder
300 Word line decoder
310 Local word line decoder
320 Ternary gate driver
330 Global word line decoder
340 L1 word line decoder
350 L2 word line decoder
360 Global word line decoder
400 Bit line bias control circuit
500 Word line bias control circuit
571 Lower layer sense amplifier
581 Upper layer sense amplifier
591 Sense amplifier
600 Access control circuit

1. A memory control circuit comprising a plurality of stages of memory decoders configured to select a specific cell of a memory according to a specified address and apply a predetermined voltage to two ends of the specific cell,
wherein a first specific stage that is at least one of the plurality of stages includes:
a first transistor and a second transistor each provided according to a value to be written to the specific cell; and
a third transistor and a fourth transistor that bring the specific cell into a non-selected state.

2. The memory control circuit according to claim 1, wherein
the first and second transistors have outputs connected to each other and become exclusively conductive.

3. The memory control circuit according to claim 1, wherein
the first transistor becomes conductive either when writing a first value to the specific cell or when reading a value from the specific cell, and
the second transistor becomes conductive when writing a second value to the specific cell.

4. The memory control circuit according to claim 1, wherein
the third and fourth transistors are connected in series, and when bringing the specific cell into the non-selected state, the third and fourth transistors become conductive and apply a voltage to a non-selection line.

5. The memory control circuit according to claim 1, wherein
a maximum value of a gate-to-diffusion region voltage of the first to fourth transistors is smaller than the voltage applied to the two ends of the specific cell.

6. The memory control circuit according to claim 1, wherein
a maximum amplitude of a gate voltage of the first to fourth transistors is smaller than the voltage applied to the two ends of the specific cell.

7. The memory control circuit according to claim 1, wherein
a second specific stage that is at least one stage of the memory decoders other than the first specific stage includes:
a driver that generates voltages with three values; and
a fifth transistor and a sixth transistor that become exclusively conductive according to an output of the driver.

8. The memory control circuit according to claim 7, wherein
the fifth transistor becomes conductive by a highest voltage among the three values either when writing the first value to the specific cell or when reading a value from the specific cell, and becomes conductive by an intermediate voltage of the three values when writing the second value to the specific cell.

9. The memory control circuit according to claim 7, wherein
when bringing the specific cell into the non-selected state, the sixth transistor becomes conductive and applies a voltage to a non-selection line.

10. The memory control circuit according to claim 7, wherein
in a case where the memory decoder above the second specific stage is in a non-selected state, the fifth transistor becomes conductive and applies a voltage to a non-selection line.

11. The memory control circuit according to claim 7, wherein
the second specific stage is arranged on a side of the memory with respect to the first specific stage.

12. The memory control circuit according to claim 1, wherein
the memory is a cross-point memory,
the specific cell is arranged at an intersection of a bit line and a word line, and
the plurality of stages of the memory decoders is provided for each of the bit line and the word line.

13. A memory control circuit comprising a plurality of stages of memory decoders configured to select a specific cell of a memory according to a specified address and apply a predetermined voltage to two ends of the specific cell,
wherein a specific stage that is at least one of the plurality of stages includes:
a driver that generates voltages with three values; and
a first transistor and a second transistor that become exclusively conductive according to an output of the driver.

14. The memory control circuit according to claim 13, wherein
the first transistor becomes conductive by a highest voltage among the three values either when writing a first value to the specific cell or when reading a value from the specific cell, and becomes conductive by an intermediate voltage of the three values when writing a second value to the specific cell.

15. The memory control circuit according to claim 13, wherein
when bringing the specific cell into a non-selected state, the second transistor becomes conductive and applies a voltage to a non-selection line.

16. The memory control circuit according to claim 13, wherein
in a case where the memory decoder above the specific stage is in a non-selected state, the first transistor becomes conductive and applies a voltage to a non-selection line.

17. The memory control circuit according to claim 13, wherein
a maximum value of a gate-to-diffusion region voltage of the first and second transistors is smaller than the voltage applied to the two ends of the specific cell.

18. The memory control circuit according to claim 13, wherein
a maximum amplitude of a gate voltage of the first and second transistors is smaller than the voltage applied to the two ends of the specific cell.
